(19) United States
(12) Patent Application Publication
(10) Pub. No.: US 2015/0187895 A1
(43) Pub. Date: Jul. 2, 2015

(54) THIN FILM TRANSISTOR STRUCTURE

(71) Applicant: AU OPTRONICS CORP., Hsin-Chu (TW)

(72) Inventors: Cheng-Yang HSU, Hsin-Chu (TW); Po-Yuan SHEN, Hsin-Chu (TW); Chia-Fang CHEN, Hsin-Chu (TW)

(21) Appl. No.: 14/445,385

(22) Filed: Jul. 29, 2014

(30) Foreign Application Priority Data
Dec. 31, 2013 (TW) 102149309

(51) Int. Cl. H01L 29/417; H01L 27/12; H01L 29/786

(52) U.S. Cl. CPC H01L 29/41758; H01L 29/78669; H01L 29/78678; H01L 27/124

(57) ABSTRACT

A thin film transistor structure includes a substrate, a gate structure, a semiconductor active layer, a drain structure and a source structure. The gate structure and the semiconductor active layer are disposed above the substrate. The drain structure and the source structure are disposed on a first surface of the semiconductor active layer. At least a gap is formed between the source structure and the drain structure. The gap is extended along the first surface of the semiconductor active layer and is located in a projection area of the gate structure. A first portion of the gap includes a first straight segment, a first curved segment and a second curved segment. The first curved segment and the second curved segment are connected to a first end and a second end of the first straight segment, respectively. The first curved segment and the second curved segment have opposite bending directions.

### RELATED APPLICATION

This application claims priority to Taiwan Application Serial Number 102149309, filed Dec. 31, 2013, which is herein incorporated by reference.

### TECHNICAL FIELD

The present disclosure relates to a transistor structure, and more particularly to a thin film transistor structure.

### BACKGROUND

In a conventional thin film transistor liquid crystal display (TFT-LCD) structure, a driving circuit is implemented by welding a plurality of driving ICs, made by complementary metal oxide semiconductor (CMOS) manufacturing process, around the LCD panel. However, in the aforementioned structure, the conventional TFT-LCD has relatively high dependence on the driving ICs, relatively high cost, and relatively low integration degree.

Because the large panels with ultra-high-resolution are the main trend now and for increasing the integration degree of TFT-LCD, more and more TFT-LCDs are manufactured by using the gate on array (GOA). Basically, GOA is referred to as a driving IC manufacturing technology by directly manufacturing the gate driving circuit on the array substrate, instead of using an external silicon wafer and the CMOS manufacturing process. FIG. 1 is a schematic top view of a GOA circuit element in a conventional TFT-LCD. As shown, the GOA circuit element 100 in a conventional TFT-LCD includes a glass substrate 110, a gate layer 120, a drain layer 130 and a source layer 140; wherein the gate layer 120, the drain layer 130 and the source layer 140 are disposed above the glass substrate 110. A U-shaped gap 140, formed above the gate layer 120 and between the drain layer 130 and the source layer 140, is functioned as a channel layer area 150. The drain layer 130 includes a strip portion 132 and a plurality of finger-like portions 134. As shown in FIG. 1, it is to be noted that the strip portion 132 is located above the glass substrate 110 but not above the gate layer 120.

For providing a larger output voltage, it is understood that the number of GOA circuit elements increases with the size of the display panel. However, there is also a demand for a slimmer frame of a TFT-LCD. Therefore, one object of the present invention is to provide a GOA circuit element with reduced size thereby having a slim frame.

### SUMMARY

An aspect of the present disclosure is to provide a thin film transistor structure capable of reducing element size.

The present disclosure provides a thin film transistor structure, which includes a substrate, a gate structure, a semiconductor active layer, a drain structure and a source structure. The gate structure is disposed on the substrate. The semiconductor active layer is disposed above the substrate. The drain structure is disposed on a first surface of the semiconductor active layer. The source structure is disposed on the first surface of the semiconductor active layer. At least a gap is formed between the source structure and the drain structure. The gap is extended along the first surface of the semiconductor active layer and is located in a projection area of the gate structure. A first portion of the gap includes a first straight segment, a first curved segment and a second curved segment. The first curved segment and the second curved segment are connected to a first end and a second end of the first straight segment, respectively. The first curved segment and the second curved segment have opposite bending directions.

The present disclosure further provides a thin film transistor structure, which includes a substrate, a gate structure, a semiconductor active layer, a drain structure and a source structure. The gate structure is disposed on the substrate. The semiconductor active layer is disposed above the substrate. The drain structure is disposed on a first surface of the semiconductor active layer and includes a strip portion extending in a first direction and a plurality of finger-shaped portions parallel with one another. The plurality of finger-shaped portions are perpendicular to the strip portion and extend outwardly from the strip portion. The source structure is disposed on the first surface of the semiconductor active layer. A plurality of gaps are formed between the source structure and the strip portion, and the plurality of gaps are located in a projection area of the gate structure.

In summary, through designing the gaps formed between the drain structure and the source structure to be located in the projection area of the gate semiconductor layer, the gaps functioning as the channel layer can have a maximum effectiveness. Thus, the circuit element size can be effectively reduced, the integration degree of circuit elements is improved, and a larger output voltage can be outputted. Therefore, the issue of having a larger frame resulted from the increasing number of circuit element in GOA can be improved by the thin film transistor structure of the present disclosure.

### BRIEF DESCRIPTION OF THE DRAWINGS

The present disclosure will become more readily apparent to those ordinarily skilled in the art after reviewing the following detailed description and accompanying drawings, in which:

FIG. 1 is a schematic top view of a GOA circuit element in a conventional TFT-LCD;

FIGS. 2A, 2B are schematic top views of a thin film transistor structure in accordance with an embodiment of the present disclosure;

FIG. 2C is a schematic cross-sectional view of a part of the thin film transistor structure, taken along the line A-A′ in FIG. 2A;

FIG. 3 is a schematic top view of a thin film transistor structure in accordance with another embodiment of the present disclosure;

FIG. 4 is a schematic top view of a thin film transistor structure in accordance with still another embodiment of the present disclosure; and

FIG. 5 is a schematic top view of a thin film transistor structure in accordance with yet another embodiment of the present disclosure.

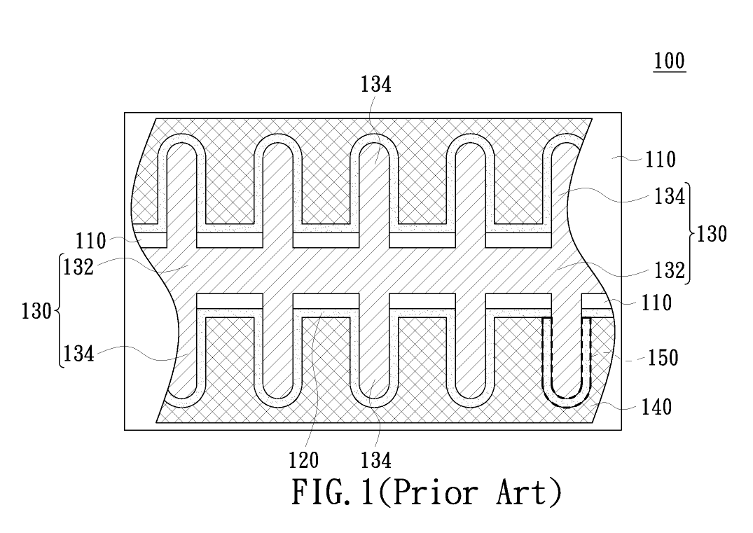

### DETAILED DESCRIPTION OF PREFERRED EMBODIMENTS

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

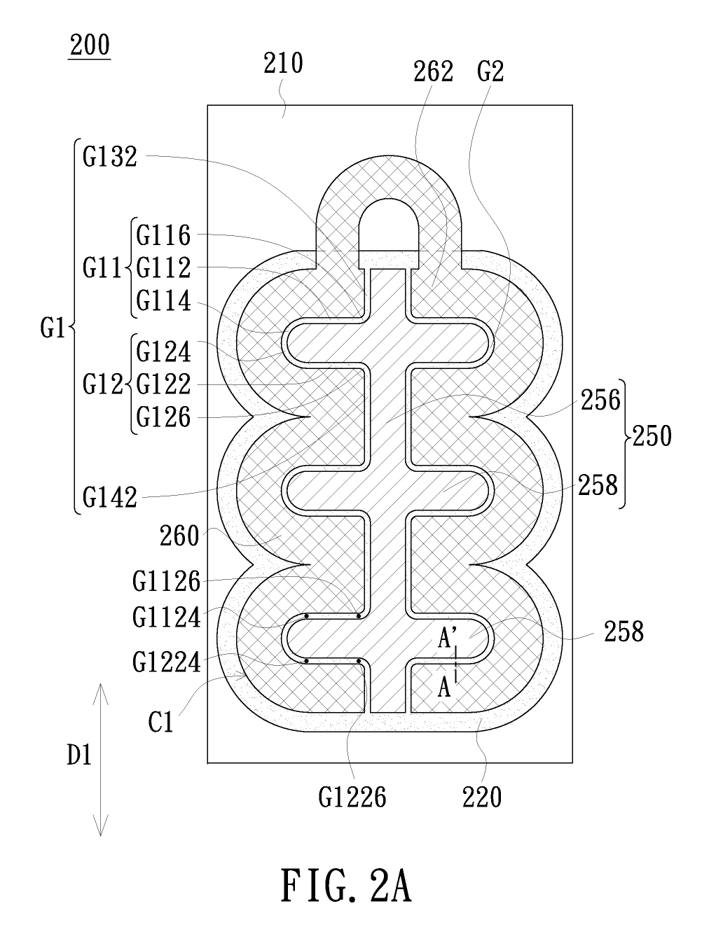

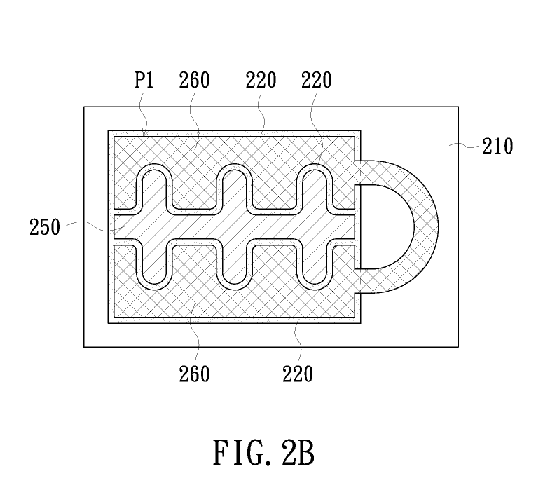

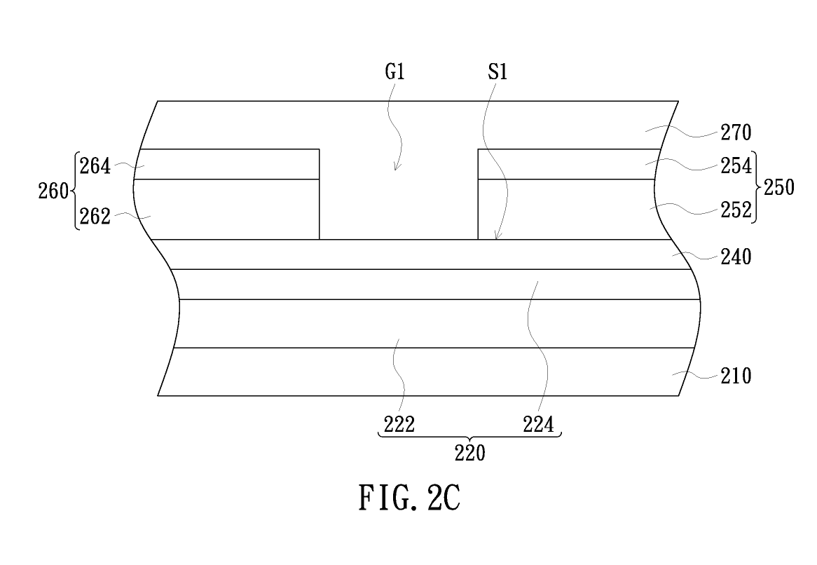

FIGS. 2A, 2B are schematic top views of a thin film transistor structure in accordance with an embodiment of the present disclosure. FIG. 2C is a schematic cross-sectional view of a part of the thin film transistor structure, taken along the line A-A′ in FIG. 2A. Please refer to FIGS. 2A, 2B and 2C. The thin film transistor structure 200 in the present embodiment includes a substrate 210, a gate structure 220, a semiconductor active layer 240, a drain structure 250 and a source structure 260. In another embodiment, the thin film transistor structure 200 may further include a protective layer 270.

To clearly distinguish the source structures 260 thereby facilitating a better understanding of the present disclosure, it is to be noted that each source structure 260 illustrated in FIG. 2A is modified to have a curved portion C1 thereby having a horseshoe-shaped structure; wherein these horseshoe-shaped source structures 260 are arranged in two parallel rows. However, it is understood that the commonly-seen source structure 260, made by a general manufacturing process, has a linear portion P1 as illustrated in FIG. 2B. In addition, it is to be noted that the description of the thin film transistor structure 200 in the present embodiment in follow is based on FIGS. 2A and 2C.

Please refer to FIG. 2C first. The substrate 210 may be a light-transmitting substrate, such as a glass substrate. The gate structure 220 is formed on a surface of the substrate 210. The semiconductor active layer 240 is formed on a surface of the gate structure 220. The gate structure 220 includes a gate conductor layer 222 and a gate dielectric layer 224. Specifically, the gate conductive layer 222 is formed on the surface of the substrate 210. The gate dielectric layer 224 is formed between the substrate 210 and the semiconductor active layer 240; specifically, the gate dielectric layer 224 is formed between the gate conductive layer 222 and the semiconductor active layer 240. Both of the drain structure 250 and the source structure 260 are formed on a first surface S1 of the semiconductor active layer 240. In one embodiment, the protective layer 270 is formed to cover the drain structure 250, the source structure 260 and the semiconductor active layer 240. The drain structure 250 includes a drain semiconductor contact structure 252 and a drain wire structure 254; wherein the drain wire structure 254 is formed on the drain semiconductor contact structure 252. The source structure 260 includes a source semiconductor contact structure 262 and a source wire structure 264; wherein the source wire structure 264 is formed on the source semiconductor contact structure 262. The semiconductor active layer 240 is, for example, an amorphous silicon layer, a polysilicon layer or an indium gallium zinc oxide. Both of the drain semiconductor contact structure 252 and the source semiconductor contact structure 262 are, for example, N-type amorphous silicon or polysilicon layers. Furthermore, both of the drain wire structure 254 and the source wire structure 264 can be made by transparent conductors.

Please refer to FIGS. 2A and 2C. The drain structure 250 includes a strip portion 256 extending in a direction D1 and a plurality of finger-shaped portions 258 parallel with one another. The finger-shaped portions 258 are perpendicular or approximately perpendicular to the strip portion 256 and extend outwardly from two opposite sides of the strip portion 256; in other words, the finger-shaped portions 258 are arranged to be parallel with one another along the first direction D1. At least one gap G1 is formed between the drain structure 250 and the source structure 260.

Specifically, a plurality of gaps are formed between the source structure 260 and the strip portion 256 and the finger-shaped portions 258 of the drain structure 250. The gap formed between the source structure 260 and the strip portion 256 of the drain structure 250 is located in the projection area of the gate structure 220. The gap formed between the source structure 260 and the strip portion 256 of the drain structure 250 is substantially vertical to the finger-shaped portions 258. Specifically, the gap G1 is the gap formed between the drain semiconductor contact structure 252 and the source semiconductor contact structure 262. The gap G1 is extended along the first surface 51 of the semiconductor active layer 240 and is located in the projection area of the gate structure 220.

More specifically, the gap G1 is extended along the first surface Si of the semiconductor active layer 240 and is located in the projection area of the gate conductor layer 222 of the gate structure 220, as illustrated in FIGS. 2A and 2C. The gap G1 includes a first portion G11 and a second portion G12, as illustrated in FIG. 2A. The first portion G11 includes a first straight segment G112, a first curved segment G114 and a second curved segment G116. The first curved segment G114 and the second curved segment G116 are connected to a first end G1124 and a second end G1126 of the first straight segment G112, respectively; wherein the first curved segment G114 and the second curved segment G116 have opposite bending directions. The second portion G12 of the gap G1 includes a second straight segment G122, a third curved segment G124 and a fourth curved segment G126. The third curved segment G124 and the fourth curved segment G126 are connected to a first end G1224 and a second end G1226 of the second straight segment G122, respectively; wherein the third curved segment G124 and the fourth curved segment G126 have opposite bending directions. The third curved segment G124 is connected to the first curved segment G114 of the first portion G11. In one embodiment, the first curved segment G114, the second curved segment G116, the third curved segment G124 and the fourth curved segment G126 substantially can be right-angle segments.

The second curved segment G116 and the fourth curved segment G126 are formed in the junction area of the strip portion 256 and the respective finger-shaped portion 258 of the drain structure 250. In other words, the junction areas of the strip portion 256 and the finger-shaped portions 258 of the drain structure 250 are formed with a plurality of arcuate curved gaps (e.g., the second curved segments G116 and the fourth curved segments G126); wherein the aforementioned arcuate curved gaps are located in the projection area of the gate structure 220. The gap G1 further includes a third straight segment G132 and a fourth straight segment G142. The two ends of the second curved segment G116 are connected to the third straight segment G132 and the second end G1126 of the first straight segment G112, respectively. The two ends of the fourth curved segment G126 are connected to the fourth straight segment G142 and the second end G1226 of the second straight segment G122, respectively.

The above description is for describing the structure of the gap G1 formed between the drain structure 250 and one single source structure 260. It is understood that there will be two gaps G1, G2 when another source structure 262 is introduced in; wherein the source structure 262 is located opposite to the source structure 260. In addition, by viewing the drain structure 250 and the pair of source structures 260, 262 as a whole, the drain structure 250 has a cross-shaped structure and both of the source structures 260, 262 have horseshoe-shaped structures. Similar to the gap G1, the gap G2 is extended along the first surface S1 of the semiconductor active layer 240 and is located in the projection area of the gate conductor layer 222 of the gate structure 220. In addition, it is understood that the gap G2 is a mirror image of the gap G1 and the gap G2 formed between the drain structure 250 and the source structure 262 has a structure same as that of the gap G1 formed between the drain structure 250 and the source structure 260; and no redundant detail is to be given herein. Because the two opposite source structures 260, 262 corporately use one drain structure 250 and both of the gaps G1, G2 respectively formed between the drain structure 250 and the source structures 260, 262 are located in the projection area of the gate conductor layer 222, the drain structure 250 and the source structures 260, 262 can have reduced element size; and consequentially the thin film transistor structure of the present invention can have reduced element size. In addition, it is to be noted that the cross-shaped drain structure 250 may be used to output, for example, a cross signal.

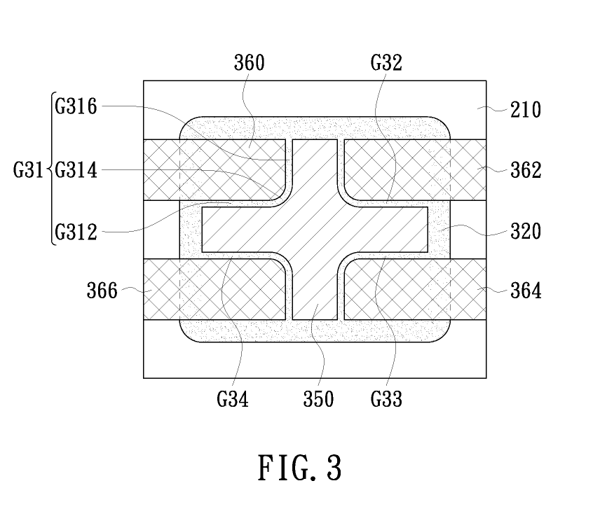

FIG. 3 is a schematic top view of a thin film transistor structure in accordance with another embodiment of the present disclosure. As shown, the drain structure 350 in the present embodiment has a structure similar to that of the drain structure 250 and also has a cross-shaped structure thereby being capable of outputting a cross signal. The drain structure 350 is formed among the four strip-shaped source structures 360, 362, 364 and 366. Gaps G31, G32, G33 and G34 are formed between the drain structure 350 and the source structures 360, 362, 364 and 366, respectively. All of the gaps G31, G32, G33 and G34 are located in the projection area of the gate structure 320. Specifically, all the gaps G31, G32, G33 and G34 are located in the projection area of the gate conductor layer (not shown) of the gate structure 320. The gate structure 320 has a structure same as that of the aforementioned gate structure 220; and no redundant detail is to be given herein. The gap G31 includes a first straight segment G312, a curved segment G314 and a second straight segment G316. The first straight segment G312 and the second straight segment G316 are connected to the two ends of the curved segment G314. Each one of the gaps G32, G33 and G34 has a structure same as that of the gap G31; and no redundant detail is to be given herein. In addition, it is to be noted that the curved segment of each one of the gaps G31, G32, G33 and G34 has a respective bending direction and substantially can be a right-angle segment.

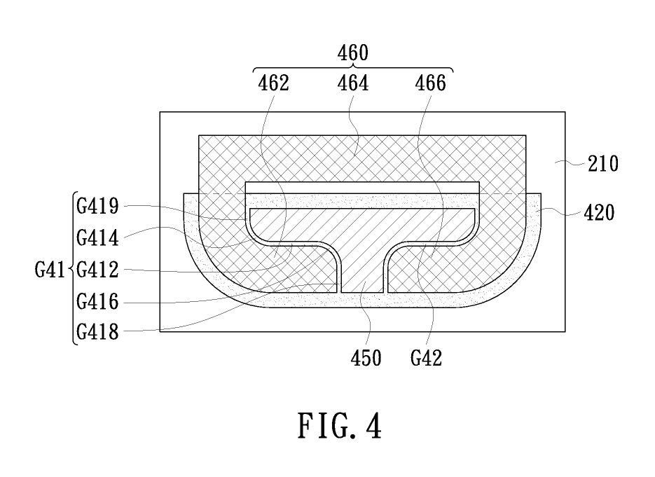

FIG. 4 is a schematic top view of a thin film transistor structure in accordance with still another embodiment of the present disclosure. As shown, the drain structure 450 in the present embodiment has a T-shaped structure, which is different to the cross-shaped drain structures 250, 305 in the above embodiments. A source structure 460, disposed with the T-shaped drain structure 450, includes two opposite half-U-shaped curved portions 462, 466 and a straight portion 464. The curved portions 462, 466 are connected to two ends of the straight portion 464, thereby forming a complete source structure 460. The curved portions 462, 466 of the source structure 460 are located in the projection area of the gate structure 420. It is to be noted that the straight portion 464 is not located in the projection area of the gate structure 420. A gap G41 is formed between the drain structure 450 and the curved portion 462 of the source structure 460. A gap G42 is formed between the drain structure 450 and the curved portion 466 of the source structure 460.

Both of the gaps G41, G42 are located in the projection area of the gate structure 420. Specifically, both of the gaps G41, G42 are located in the projection area of the gate conductor layer (not shown) of the gate structure 420. The gap G41 includes a first straight segment G412, a first curved segment G414, a second curved segment G416, a second straight segment G418 and a third straight segment G419. The two ends of the first curved segment G414 are connected to one end of the first straight segment G412 and one end of the third straight segment G419, respectively. The two ends of the second curved segment G416 are connected to another end of the first straight segment G412 and one end of the second straight segment G418, respectively. The first curved segment G414 and the second curved segment G416 have opposite bending directions. In summary, the two gaps G41, G42 have the same structure. The main difference between the two gaps G41, G42 is that the curved segments of the two gaps G41, G42 have opposite bending directions thereby the gap G41 is a mirror image of the gap G42; and no redundant detail is to be given herein.

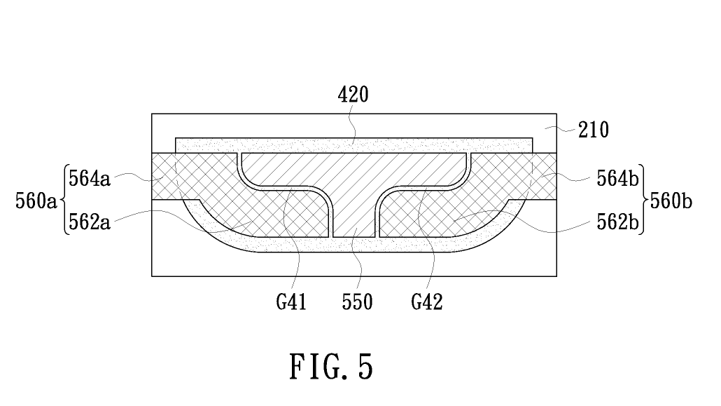

FIG. 5 is a schematic top view of a thin film transistor structure in accordance with yet another embodiment of the present disclosure. As shown, the drain structure 550 in the present embodiment has a structure similar to that of the drain structure 450 and also has a T-shaped structure. The main difference between the drain structures 450, 550 is that the two have different source structures to be disposed with. As shown in FIG. 5, the drain structure 550 is disposed with two source structures 560a, 560b. The source structure 560a includes a half-U-shaped first curved portion 562a and a first straight portion 564a. The first straight portion 564a is connected to one end of the first curved portion 562a. The source structure 560b includes a half-U-shaped second curved portion 562b and a second straight portion 564b. The second straight portion 564b is connected to one end of the second curved portion 562b. The first straight portion 564a and the second straight portion 564b have opposite extending directions. A gap G41 is formed between the drain structure 550 and the first curved portion 562a of the source structure 560a. A gap G42 is formed between the drain structure 550 and the second curved portion 562b of the source structure 560b. Both of the gaps G41, G42 are located in the projection area of the gate structure 420. Specifically, both of the gaps G41, G42 are located in the projection area of the gate conductor layer (not shown) of the gate structure 420. In summary, the two gaps G41, G42 have the same structure. The main difference between the two gaps G41, G42 is that the curved segments of the two gaps G41, G42 have opposite bending directions thereby the gap G41 is a mirror image of the gap G42; and no redundant detail is to be given herein.

In summary, through designing the gaps formed between the drain structure and the source structure to be located in the projection area of the gate semiconductor layer, the gaps functioning as the channel layer can have a maximum effectiveness. Thus, the circuit element size can be effectively reduced, the integration degree of circuit elements is improved, and a larger output voltage can be outputted. Therefore, the issue of having a larger frame resulted from the increasing number of circuit element in GOA can be improved by the thin film transistor structure of the present disclosure.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A thin film transistor structure, comprising:
a substrate;
a gate structure, disposed on the substrate;
a semiconductor active layer, disposed above the substrate;
a drain structure, disposed on a first surface of the semiconductor active layer; and
a source structure, disposed on the first surface of the semiconductor active layer,
wherein at least a gap is formed between the source structure and the drain structure, the gap is extended along the first surface of the semiconductor active layer and is located in a projection area of the gate structure, a first portion of the gap comprises a first straight segment, a first curved segment and a second curved segment, the first curved segment and the second curved segment are connected to a first end and a second end of the first straight segment, respectively, and the first curved segment and the second curved segment have opposite bending directions.

2. The thin film transistor structure according to claim 1, wherein the gate structure comprises:
a gate dielectric layer; and
a gate conductor layer,
wherein the gate dielectric layer is formed between the gate conductor layer and the semiconductor active layer.

3. The thin film transistor structure according to claim 2, wherein a second portion of the gap comprises a second straight segment, a third curved segment and a fourth curved segment, the third curved segment and the fourth curved segment are connected to a first end and a second end of the second straight segment, respectively, and the third curved segment and the fourth curved segment have opposite bending directions.

4. The thin film transistor structure according to claim 1, wherein the drain structure comprises a drain semiconductor contact structure and a drain wire structure connected with each other, wherein the source structure comprises a source semiconductor contact structure and a source wire structure connected with each other.

5. The thin film transistor structure according to claim 4, wherein a second portion of the gap comprises a second straight segment, a third curved segment and a fourth curved segment, the third curved segment and the fourth curved segment are connected to a first end and a second end of the second straight segment, respectively, and the third curved segment and the fourth curved segment have opposite bending directions.

6. The thin film transistor structure according to claim 4, wherein the gap is a gap formed between the drain semiconductor contact structure and the source semiconductor contact structure.

7. The thin film transistor structure according to claim 6, wherein a second portion of the gap comprises a second straight segment, a third curved segment and a fourth curved segment, the third curved segment and the fourth curved segment are connected to a first end and a second end of the second straight segment, respectively, and the third curved segment and the fourth curved segment have opposite bending directions.

8. The thin film transistor structure according to claim 4, wherein the drain semiconductor contact structure and the source semiconductor contact structure are N-type amorphous silicon or polysilicon layers.

9. The thin film transistor structure according to claim 8, wherein a second portion of the gap comprises a second straight segment, a third curved segment and a fourth curved segment, the third curved segment and the fourth curved segment are connected to a first end and a second end of the second straight segment, respectively, and the third curved segment and the fourth curved segment have opposite bending directions.

10. The thin film transistor structure according to claim 1, wherein a second portion of the gap comprises a second straight segment, a third curved segment and a fourth curved segment, the third curved segment and the fourth curved segment are connected to a first end and a second end of the second straight segment, respectively, and the third curved segment and the fourth curved segment have opposite bending directions.

11. A thin film transistor structure, comprising:
a substrate;
a gate structure, disposed on the substrate;
a semiconductor active layer, disposed above the substrate;
a drain structure, disposed on a first surface of the semiconductor active layer and comprising a strip portion extending in a first direction and a plurality of finger-shaped portions parallel with one another, wherein the plurality of finger-shaped portions are perpendicular to the strip portion and extend outwardly from the strip portion; and
a source structure, disposed on the first surface of the semiconductor active layer, wherein a plurality of gaps are formed between the source structure and the strip portion, and the plurality of gaps are located in a projection area of the gate structure.

12. The thin film transistor structure according to claim 11, wherein the plurality of finger-shaped portions are arranged in parallel along the first direction.

13. The thin film transistor structure according to claim 11, wherein the drain structure comprises a drain semiconductor contact structure and a drain wire structure, wherein the source structure comprises a source semiconductor contact structure and a source wire structure, wherein the plurality of gaps are gaps formed between the drain semiconductor contact structure and the source semiconductor contact structure.

14. The thin film transistor structure according to claim 11, wherein a plurality of curved gaps are formed in a junction area of the strip portion and the plurality of finger-shaped portions, and the plurality of curved gaps are located in a projection area of the gate structure.

15. The thin film transistor structure according to claim 14, wherein the plurality of finger-shaped portions are arranged in parallel along the first direction.

16. The thin film transistor structure according to claim 14, wherein the drain structure comprises a drain semiconductor contact structure and a drain wire structure, wherein the source structure comprises a source semiconductor contact structure and a source wire structure, wherein the plurality of gaps are gaps formed between the drain semiconductor contact structure and the source semiconductor contact structure.
